(19) United States
(12) Patent Application Publication
(10) Pub. No.: US 2007/0075306 A1
(43) Pub. Date: Apr. 5, 2007

(54) Light emitting device

(75) Inventors: Toshimasa Hayashi, Aichi-ken (JP); Takumi Narita, Aichi-ken (JP); Hiroaki Kawaguchi, Aichi-ken (JP); Peter Pachler, Graz-St. Peter (AT); Christian Hochfilzer, Graz (AT); Stefan Tasch, Jennersdorf (AT)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignees: TOYODA GOSEI CO., LTD., Aichi-ken (JP); LEXEDIS LIGHTING GMBH, Jennersdorf (AT); TRIDONIC OPTOELECTRONICS GESELLSCHAFT MIT BESCHRANKTER-HAFTUNG, Jennersdorf (AT)

(21) Appl. No.: 11/524,520

(22) Filed: Sep. 21, 2006

(30) Foreign Application Priority Data
Sep. 22, 2005 (JP) 2005-276858
Sep. 21, 2006 (JP) 2006-256481

(51) Int. Cl. H01L 29/06

(52) U.S. Cl. 257/13

(57) ABSTRACT

A light emitting device having an emitting element and an element mounting portion on which the emitting element is mounted. The element mounting portion is formed of aluminum nitride.

The present application is based on Japanese patent application Nos. 2005-276858 and 2006-256481, the entire contents of which are incorporated herein by reference.

### BACKGROUND OF THE INVENTION

1. Field of the Invention

The present invention relates to a light emitting device using an LED (=light emitting diode) element as a light source and, more particularly, to a light emitting device that is capable of being designed in higher degree of freedom according to the request of a customer or the like, and is capable of meeting a larger light output and a higher brightness.

2. Description of the Related Art

Light emitting devices using an LED element as a light source are conventionally known. Since the LED elements are manufactured by the semiconductor manufacturing process, they are excellent in mass productivity. Further, they are maintenance-free and do not contain mercury or other harmful substances. Therefore, the demand thereof is expanding in cell-phones and other portable appliances intensively reduced in size.

Recently, according as LED elements with a large light output have been developed, they are expected to be applied to a vehicle light and a lighting system. In particular, a light emitting device to radiate white light is widely proposed as a light source to replace a fluorescent lamp.

In order to have an LED element with a higher brightness and a larger output, it is known that the LED element is provided with a large chip size (for example, 1 mm square size) and driven by a large current. However, since heat generated corresponding to current fed increases, the emission efficiency of the LED element may lower. Further, the heat may promote the photo-deterioration of a sealing resin such as epoxy resin or silicon resin for sealing the LED element, and the light output may be lowered.

To solve these problems, a new light emitting device has been proposed in which an LED package, as a package for sealing an LED element, is mounted on a heat sink made of Cu excellent in heat conductivity, so that heat generated from the LED element can be radiated in the shortest distance through its package substrate (see, e.g., Satoshi Okubo, “LED surpassing fluorescent lamp”, Nikkei Electronics, Nikkei BP, Apr. 25, 2005, No. 898, p. 87).

The light emitting device disclosed by Satoshi Okubo comprises the heat sink made of Cu, the package mounted on the heat sink, and a mold resin covering the periphery of the package, and the LED element in the package is sealed by a resin with phosphors dispersed therein, and heat generated from the LED element is radiated to the Al substrate on which the light emitting device is mounted.

However, the light emitting device disclosed by Satoshi Okubo is not capable of being designed in higher degree of freedom according to the request of a customer and the like. Namely, in order to present a light emitting device of large output type which can have a high reliability even when it is subjected to a large thermal load, it is needed to design the entire device in excellent balance in consideration of its manufacturing cost and lifetime. For example, it is hard to design it without changing the design to meet plural demands, e.g., the installation environment of the light emitting device, emission color, light output, light distribution characteristics etc.

### SUMMARY OF THE INVENTION

It is an object of the invention to provide a light emitting device that is capable of being designed in higher degree of freedom according to the request of a customer or the like, and is capable of meeting a larger light output and a higher brightness.
(1) According to one aspect of the invention, a light emitting device comprises:

an emitting element; and

an element mounting portion on which the emitting element is mounted,

wherein the element mounting portion comprises aluminum nitride.

In the invention (1) , heat generated from the light emitting element can be efficiently externally discharged by the element mounting portion with a high thermal conductivity to allow the continuous and large-current operation of the light emitting element.
(2) According to another aspect of the invention, a light emitting device comprises:

an emitting element;

an element mounting portion on which the emitting element is mounted; and

a case comprising an opening to extract light emitted from the light emitting element, and a wiring portion for the element mounting portion and an external electrical connection, the wiring portion being provided on a mounting surface on an opposite side to a light extraction side of the opening.

In the invention (2), the power supply path can be separated from the heat radiation path while facilitating the fixing of the element mounting portion to the case and the external electrical connection. Thus, heat generated from the light emitting element can be efficiently externally discharged by the element mounting portion with a high thermal conductivity to allow the continuous and large-current operation of the light emitting element.
(3) According to another aspect of the invention, a light emitting device comprises:

an emitting element;

an element mounting portion on which the emitting element is mounted;

a case comprising an opening to extract light emitted from the light emitting element, and a wiring portion for the element mounting portion and an external electrical connection, the wiring portion being provided on a mounting surface on an opposite side to a light extraction side of the opening; and

an optical shape portion attached to the case such that light emitted from the light emitting element is radiated in a direction according to an optical shape of the optical shape portion.

In the invention (3), in addition to the effects of the invention (2), light emitted from the light emitting element can be radiated into a desired radiation range to enhance the freedom of light distribution.
(4) According to another aspect of the invention, a light emitting device comprises:

an emitting element;

an element mounting portion on which the emitting element is mounted;

a case comprising an opening to extract light emitted from the light emitting element, and a wiring portion for the element mounting portion and an external electrical connection, the wiring portion being provided on a mounting surface on an opposite side to a light extraction side of the opening;

a wavelength converter that is operable to convert a wavelength of light emitted from the light emitting element and to generate the wavelength-converted light; and

an optical shape portion attached to the case such that light emitted from the light emitting element is radiated in a direction according to an optical shape of the optical shape portion.

In the invention (4), in addition to the effects of the invention (3), light emitted from the light emitting element can be wavelength-converted into a desired emission color to allow the selection of the emission color according to the use of the light emitting device.
(5) According to another aspect of the invention, a light emitting device comprises:

an emitting element;

an element mounting portion on which the emitting element is mounted;

a case comprising an opening to extract light emitted from the light emitting element, and a wiring portion for the element mounting portion and an external electrical connection, the wiring portion being provided on a mounting surface on an opposite side to a light extraction side of the opening; and

an optical shape portion that is operable to convert a wavelength of light emitted from the light emitting element and to radiate the wavelength-converted light in a direction according to an optical shape of the optical shape portion.

In the invention (5), in addition to the effects of the invention (4), light emitted from the light emitting element can be wavelength-converted into a desired emission color by providing the optical shape portion with the wavelength conversion function while simplifying the structure of the light emitting device.

<Advantages of the Invention>

According to the invention, the light emitting device is capable of being designed in higher degree of freedom according to the request of a customer or the like, and is capable of meeting a larger light output and a higher brightness.

### BRIEF DESCRIPTION OF THE DRAWINGS

The preferred embodiments according to the invention will be explained below referring to the drawings, wherein:

FIG. 1 is a cross sectional view showing a light emitting device in a first preferred embodiment according to the invention;

FIG. 2 is a cross sectional view showing an LED element of the first embodiment;

FIG. 3A is a plain view showing the light emitting device of the first embodiment;

FIG. 3B is a partially cut-away enlarged plain view showing an LED element mounting portion in FIG. 3A;

FIG. 4 is a cross sectional view showing a first modification of the light emitting device of the first embodiment;

FIG. 5 is a cross sectional view showing a second modification of the light emitting device of the first embodiment;

FIG. 6 is a cross sectional view showing a second modification of the light emitting device of the first embodiment;

FIG. 7 is a cross sectional view showing a light emitting device in a second preferred embodiment according to the invention;

FIG. 8 is a cross sectional view showing a light emitting device in a third preferred embodiment according to the invention;

FIG. 9 is a cross sectional view showing a light emitting device in a fourth preferred embodiment according to the invention;

FIG. 10 is a cross sectional view showing a light emitting device in a fifth preferred embodiment according to the invention;

FIG. 11 is a cross sectional view showing a light emitting device in a sixth preferred embodiment according to the invention;

FIG. 12 is a cross sectional view showing a light emitting device in a seventh preferred embodiment according to the invention;

FIG. 13 is a cross sectional view showing a modification of the light emitting device of the seventh embodiment;

FIG. 14 is a cross sectional view showing a light emitting device in an eighth preferred embodiment according to the invention;

FIG. 15 is a cross sectional view showing a light emitting device in a ninth preferred embodiment according to the invention;

FIG. 16 is a cross sectional view showing a light emitting device in a tenth preferred embodiment according to the invention;

FIG. 17 is a cross sectional view showing a light emitting device in an eleventh preferred embodiment according to the invention;

FIG. 18 is a cross sectional view showing a light emitting device in a twelfth preferred embodiment according to the invention;

FIG. 19 is a cross sectional view showing a light emitting device in a thirteenth preferred embodiment according to the invention;

FIG. 20 is a cross sectional view showing a light emitting device in a fourteenth preferred embodiment according to the invention; and

FIG. 21 is a cross sectional view showing a light emitting device in a fifteenth preferred embodiment according to the invention.

### DETAILED DESCRIPTION OF THE PREFERRED EMBODIMENTS

### First Embodiment

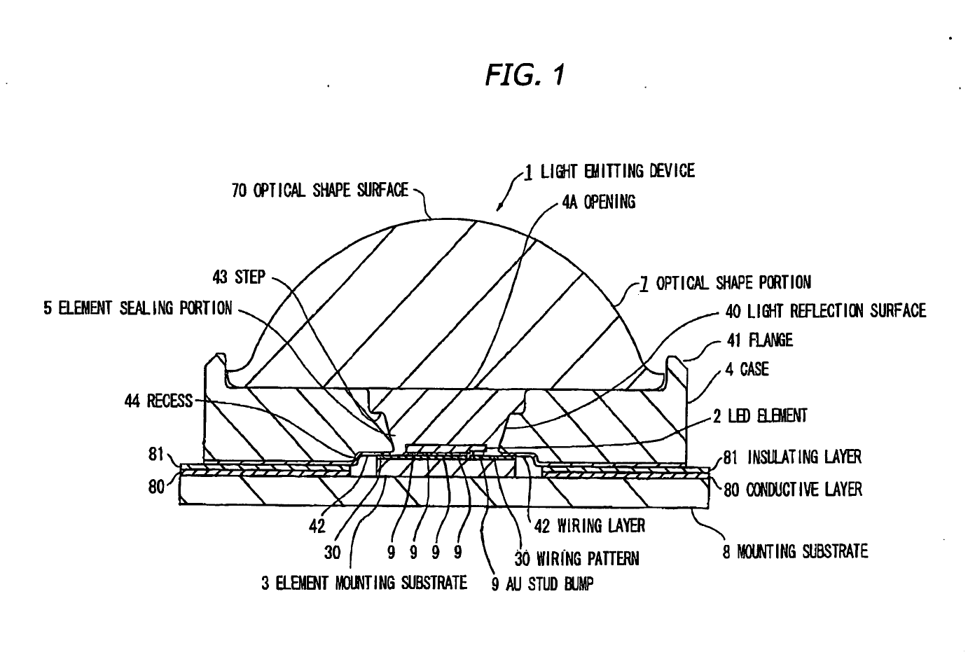

FIG. 1 is a cross sectional view showing a light emitting device in the first preferred embodiment according to the invention.

Construction of light emitting device 1

The light emitting device 1 comprises; a flip-chip type LED element 2 made of a group III nitride-based compound semiconductor, an element mounting substrate 3 as an element mounting portion for mounting the LED element 2 thereon; a case 4 as a main body of the light emitting device 1; a transparent element sealing portion 5 for sealing the LED element 2 disposed in an opening 4A of the case 4; and an optical shape portion 7 for radiating light discharged from the opening 4A in a direction depending on the shape of an optical shape surface 70. The bottom of the element mounting substrate 3 is mounted so as to contact the surface of the mounting substrate 8 with a high thermal conductivity.

The element mounting substrate 3 is made of aluminum nitride (AlN) excellent in heat conductivity, and has a wiring pattern 30, made of a conductive material, formed on the surface for mounting the LED element 2. The LED element 2 is mounted on the wiring pattern 30 through Au stud bumps 9.

The case 4 is made of Al₂O₃, and has the opening 4A provided at the center, penetrating from the surface to the bottom. The inner wall of the opening 4A is inclined so that the inside diameter can be expanded from the bottom to the light output direction, and is provided with a light reflection surface 40 with a step 43 located midway to reflect light emitted from the LED element 2 to the light output side. A flange 41 is formed on the periphery of the case 4 to position the optical shape portion 7 described later. On the mounting surface of the case 4, a wiring layer 42 made of Au is provided which is electrically connected to the wiring pattern 30 of the element mounting substrate 3, and a recess 44 is formed so that the bottom of the element mounting substrate 3 can be made flush with the mounting substrate 8 described later. The size of recess 44 is formed larger than the illustrated element mounting substrate 3 so as to be applicable to various sizes of the element mounting substrate 3.

The element sealing portion 5 to seal the LED element 2 is formed by injecting heat resistance silicone into the opening 4A.

The optical shape portion 7 is formed into a hemispherical optical shape by using a transparent resin material such that light emitted from the LED element 2 is radiated to the outside from the optical shape surface 70 of the optical shape portion 7.

The mounting substrate 8 is made of aluminum (Al), and is thereon provided with an insulating layer 80 made of polyimide, and a conductive layer 81 made of a film conductive material such as a copper foil stacked on the insulating layer 80. The insulating layer 80 and the conductive layer 81 are not formed on a portion to mount the element mounting substrate 3 so that the surface of the mounting substrate 8 can directly contact the surface of the element mounting substrate 3. Between the mounting substrate 8 and the element mounting substrate 3, a heat conductive paste such as an Ag paste or silicone grease may be coated. The bottom of the element mounting substrate 3 can be bonded to the surface of the mounting substrate 8 by using a conductive material such as solder. In this case, it is desired that a flush plating of Au is formed on the bottom of the element mounting substrate 3 and on the surface of the mounting substrate 8 to secure the solder wettability. Alternatively, after soldering and joining the element mounting substrate 3 to the mounting substrate 8, the case 4 may be mounted on the element mounting substrate 3 and mounting substrate 8 and the optical shape portion 7 may be formed.

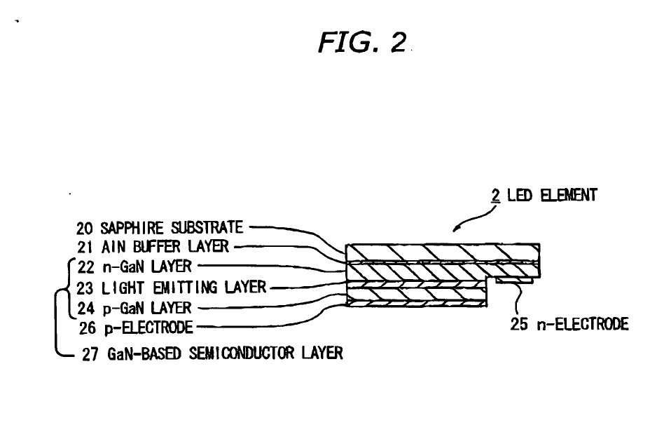

FIG. 2 is a cross sectional view showing an LED element of the first embodiment.

The LED element 2 is fabricated by using an MOCVD (Metal Organic Chemical Vapor Deposition) apparatus, and after forming an AlN buffer layer 21 on a sapphire substrate 20, a Si-doped n-GaN layer 22, a light emitting layer 23, a Mg-doped p-GaN layer 24 are sequentially grown as a GaN-based semiconductor layer 27. Then, an n-side electrode 25 is formed in an exposed portion of the n-GaN layer 22 removed by etching from the p-GaN layer 24 to the n-GaN layer 22. On the surface of the p-GaN layer 24, a p-side electrode 26 is formed. The LED element 2 emits light based on the carrier recombination of a hole and an electron in the light emitting layer 23 when a voltage is applied to the n-side electrode 25 and the p-side electrode 26, and blue light is emitted from the sapphire substrate 20 side. The LED element 2 used in this embodiment is a large size element of 1 mm square.

The fabrication method of the GaN-based semiconductor layer 27 is not particularly limited. Other than the MOCVD method, the GaN-based semiconductor layer 27 can be fabricated by the molecular beam epitaxial method (MBE method), hydride vapor phase epitaxial method (HVPE method), sputtering method, ion plating method, electron shower method etc. The structure of the LED element includes a homo structure, a hetero structure and a double hetero structure. Further, a quantum well structure (single quantum well structure or multiple quantum well structure) can be applied.

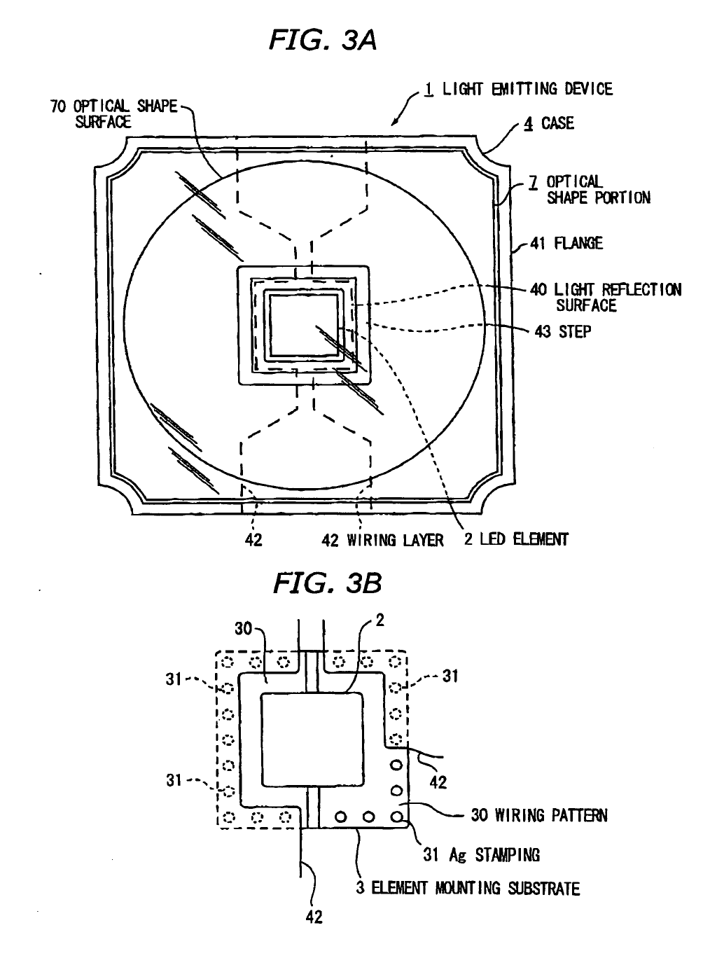

FIG. 3A is a plain view showing the light emitting device of the first embodiment, and FIG. 3B is a partially cut-away enlarged plain view showing an LED element mounting portion in FIG. 3A.

At the bottom of the case 4, as shown in FIG. 3A, a wiring layer 42 is provided corresponding to each electrode of LED element 2, and the wiring layer 42 is, as shown in FIG. 3B, bonded electrically onto the wiring pattern 30 of the element mounting substrate 3 through Ag stamping 31 provided at specified pitch. Further, the element mounting substrate 3 is integrally fixed to the bottom of the case 4 by means of the Ag stamping 31. Instead of the Ag stamping 31, it may be bonded by soldering. In this case, the solder wettability can be secured by forming a flush plating of Au on the wiring layer 42 and the wiring pattern 30.

Manufacture of light emitting device 1

In fabricating the light emitting device 1, at first, the LED element 2 is mounted on the element mounting substrate 3 having the wiring pattern 30 and the Ag stamping 31 formed thereon, by using a flip chip bonder. Alternatively, an Au layer for reducing heat transfer resistance may be provided at the bottom of the element mounting substrate 3. Then, the case 4 having the Au wiring layer 42 formed at the bottom in a separate process is positioned and thermally-compression-bonded onto the element mounting substrate 3 such that the wiring layer 42 and the wiring pattern 30 are electrically connected each other through the Ag stamping 31. Silicone is filled into the opening 4A of the case 4 by a syringe to seal the LED element 2. Then, the optical shape portion 7 is attached to the inside of the flange 41 of the case 4.

Mounting of light emitting device 1

In mounting the light emitting device 1 on the mounting substrate 8, the light emitting device 1 is positioned and fixed on the conductive layer 81 on which solder paste is coated, and the wiring layer 42 and conductive layer 81 are bonded each other by melting the solder in a reflow furnace. By the bonding, the bottom of the element mounting substrate 3 is fixed, in surface contact, to the surface of the mounting substrate 8. Alternatively, in bonding the element mounting substrate 3 to the mounting substrate 8, an Au layer (not shown) may be formed at the bottom of the element mounting substrate 3 by plating or other thin film forming process in order to enhance the contact force and reduce the heat transfer resistance between the element mounting substrate 3 and mounting substrate 8, and then the element mounting substrate 3 and mounting substrate 8 maybe solder-bonded each other by solder reflow. The Au layer may be formed on the mounting substrate 8 side rather than the element mounting substrate 3 side.

Effects of the first embodiment

The following effects can be obtained by the first embodiment.

(1) The LED element 2 is mounted on the element mounting substrate 3 with high thermal conductivity, and the element mounting substrate 3 is fixed directly to the mounting side of the case 4, and connected electrically. Thus, the light emitting device 1 can be mounted on the mounting substrate 8 without mixing the electric power supply route and the heat release route, whereby it can have excellent heat conductivity and the mounting reliability can be enhanced.

(2) Since the wiring pattern 30 formed on the element mounting substrate 3 with high heat conductivity is electrically connected to the wiring layer 42 formed on the mounting side of the case 4 through the Ag stamping 31 in the recess 44 of the case 4, the element mounting substrate 3 can be bonded in excellent conditions structurally, thermally and electrically, without losing the electrical connection property, and without requiring the process of making a through-hole for electrical connection. Accordingly, the element mounting substrate 3 can have excellent heat releasing property as a cooling member to transmit heat in the thickness direction.

(3) Since the element mounting substrate 3 and case 4 can be positioned and bonded each other while visually checking the position of the LED element 2 and element mounting substrate 3 from above the case 4, the positioning and bonding can be conducted at high precision.

(4) Sufficient heat releasing effect can be obtained even when feeding large current in case of the LED element 2 of large size. Thus, it is applicable to higher brightness and luminance demanded recently.

(5) The element mounting substrate 3 attached on the mounting side of the case 4 can be properly selected depending on the size or output of the LED element 2, and stable light emission characteristics can be obtained even when the LED element 2 is continuously operated for long hours.

(6) As for the element mounting substrate 3, the case 4 and the optical shape portion 7, materials and characteristics can be selected and combined according to the requests of customer to fabricate the light emitting device 1. Thus, the light emitting device 1 is excellent in cost performance and design freedom.

(7) Since materials equal in thermal expansion and stable in the environment are used, high reliability can be secured for a long period.

The light emitting device 1 of the first embodiment is composed to radiate blue light. Thus, for example, by providing a wavelength converter containing a wavelength converting substance such as a phosphor to be excited by the blue light on the optical path of the blue light, the light emitting device 1 can radiate white light.

First modification

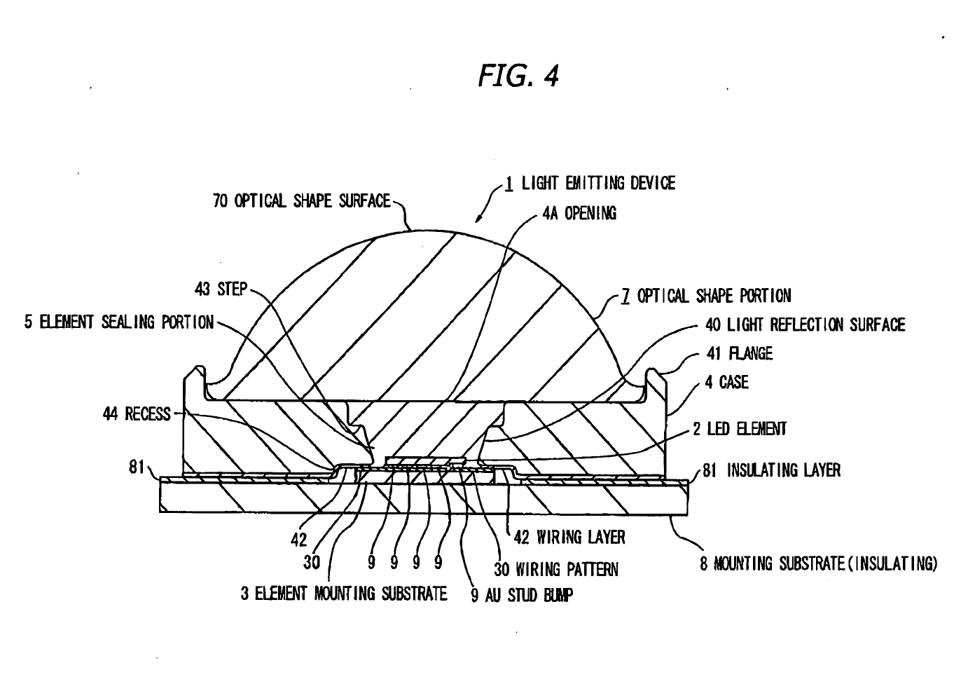

FIG. 4 is a cross sectional view showing a first modification of the light emitting device of the first embodiment.

The light emitting element 1 is modified such that the mounting substrate 8 in FIG. 1 is formed of an insulating material, glass epoxy instead of the conductive material. The bottom of the element mounting substrate 3 is contacted (in surface contact) flush with the surface of the mounting substrate 8 to form the heat releasing path. The insulating layer 80 as shown in FIG. 1 is omitted in the mounting substrate 8 using the insulating material.

By the above modified construction, heat can be, in surface form, released from the bottom of the element mounting substrate 3 to the mounting substrate 8 using the insulating material.

Second modification

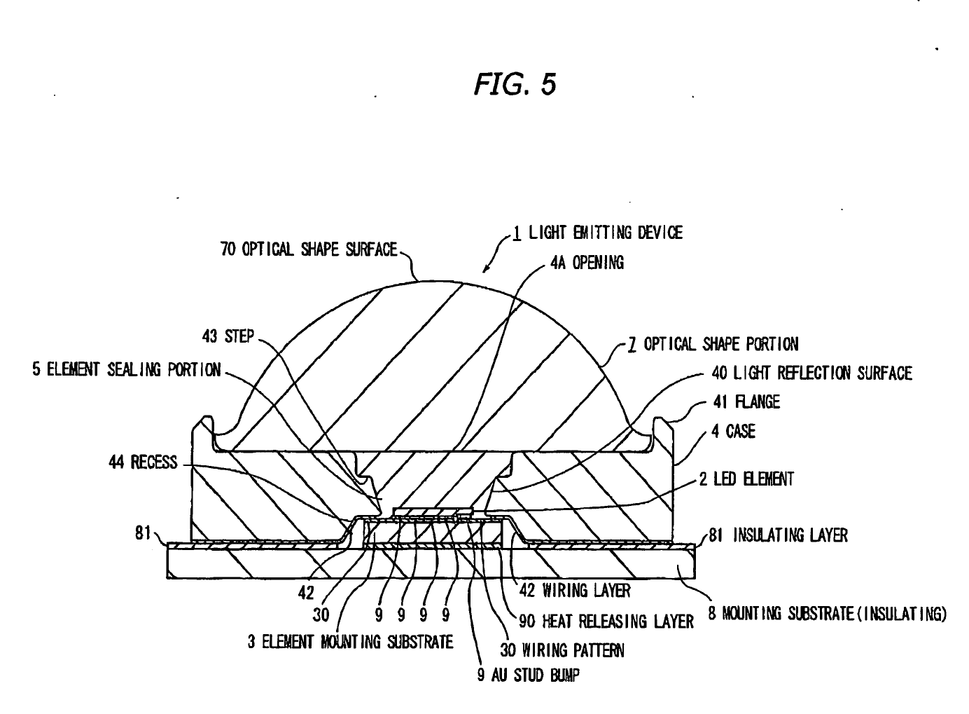

FIG. 5 is a cross sectional view showing a second modification of the light emitting device of the first embodiment.

The light emitting element 1 is modified such that a heat releasing layer 90 is formed the surface of which is made flush with the bottom of the element mounting substrate 3 and the surface of the conductive layer 81 in the light emitting element 1 as described in the first modification. The heat releasing layer 90 is formed of the same material as the conductive layer 81. The bottom of the element mounting substrate 3 is bonded to the heat releasing layer 90 on the mounting substrate 8 side through a solder bonding layer (not shown). Au flush plating is formed on the bottom of the element mounting substrate 3 and on the surface of the heat releasing layer 90 so as to secure the solder wettability.

By the above modified construction, the heat releasing path is formed through the solder bonding to the heat releasing layer 90 on the mounting substrate 8 formed of the insulating material so that heat can be, in surface form, released from the bottom of the element mounting substrate 3 to the heat releasing layer 90.

Third modification

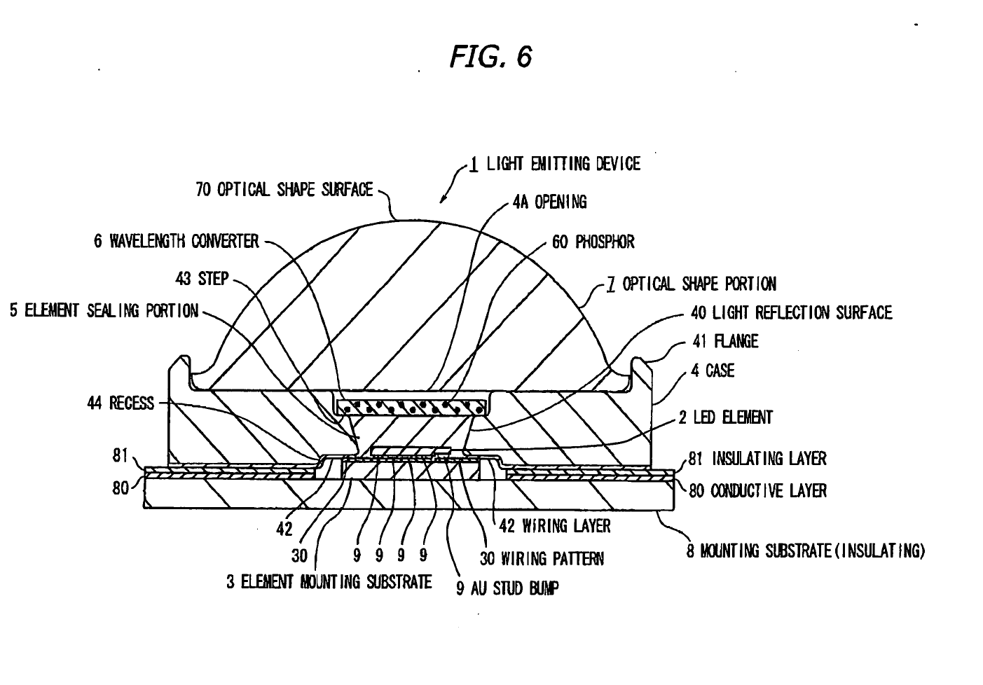

FIG. 6 is a cross sectional view showing a third modification of the light emitting device of the first embodiment.

The light emitting device 1 is modified such that a wavelength converter 6 containing a phosphor 60 to radiate yellow light based on excitation by blue light is disposed on the step 43 of the case 4 as shown in FIG. 1. The other components are similarly constructed.

The wavelength converter 6 is formed like a plate, containing the phosphor 60 comprising YAG (Yttrium Aluminum Garnet) to be excited by blue light with an emission wavelength of about 460 nm emitted from the LED element 2 in a transparent resin material. The wavelength converter 6 may be formed into a thin film by printing or other method on the surface of a thin plate formed of a transparent material excellent in light resistance such as glass. The type of the phosphor 60 may be garnet system, silicate system etc.

By the above modified construction, where the wavelength converter 6 containing the phosphor 60 comprising YAG is disposed on the step 43 of the case 4, the white light emitting device 1 with high brightness based on the blue light emitting device 1 can be easy manufactured without disturbing the installation of the optical shape portion 7. The phosphor 60 is not limited to the yellow phosphor such as YAG, but may comprise a green phosphor or a red phosphor to be excited by blue light.

Other modifications

The light emitting device 1 of the first embodiment including the abovementioned first to third modifications can be further modified in the respective components thereof as explained below.

The LED element 2 is not limited to the blue LED element, but the other LED elements 2 may be used. For example, an ultraviolet LED element with an emission wavelength of about 370 nm may be used. In this case, RGB phosphors may be included in the wavelength converter 6 such that white light can be generated by mixing red, green and blue lights to be radiated from the RGB phosphors by ultraviolet light. The LED element 2 is not limited to the large size type. For example, plural flip-chip type LED elements with a size of 300 μm square may be mounted on the element mounting substrate 3.

The LED element 2 is not limited to the LED element to emit blue light or violet light, but may include LED elements to emit green light, orange light, red light or infrared light. The material of the LED element 2 is not limited to GaN, but may include the other semiconductor materials such as AlInGaP and GaAs. The mounting of the LED element 2 is not limited to the bonding by the Au stud bump 9, but may use a solder bump or solder layer. Instead of the flip mounting-type LED element 2, a face-up type LED element 2 may be used, where electrodes disposed on the light extraction side can be wire bonded to the wiring pattern 30 on the element mounting substrate 3.

The element mounting substrate 3 may be formed of Si other than AlN which is excellent in heat release property. The Si element mounting substrate 8 can include a built-in zener diode, whereby electrostatic breakdown of the LED element 2 can be prevented. It may be also formed of Al₂O₃. The Ag stamping 31 provided on the wiring pattern 30 may be replaced by linear printing of Au or Sn.

The case 4 may be formed of materials other than Al₂O₃. For example, it can be formed of a resin material such as nylon (registered trademark) easily available and excellent in forming performance, a molded Si sinter, a metal material such as Cu and Al. It may be formed of a ceramic material such as BaTiO₃ other than Al₂O₃, or an organic material covered with a ceramic material or metal material. In case of the metal material, it is necessary to provide an insulating layer to prevent the short circuit when forming the wiring layer 42. The inside of the opening 4A may be coated with a light reflecting film formed by Al deposition or plating. The wiring layer 42 is not limited to Au, but may be formed as a laminated structure of thin layers of Ag and Pt.

The element sealing portion 5 may be formed of an inorganic sealing material such as epoxy resin and glass other than silicone excellent in heat resistance.

The wavelength converter 6 is not limited to the single member disposed on the step 43 of the case 4, but may be formed by containing a phosphor in the element sealing portion 5, placing a thin film at the bottom of the optical shape portion 7, placing a thin film on the optical shape surface 70 of the optical shape portion 7, or placing a thin film on the surface of LED element 2.

The optical shape portion 7 is not limited to the transparent resin material which is easy to mold, but may be formed of glass. The optical shape includes spherical shape, non-spherical shape and others. The optical shape portion 7 may be colored, or may be colored uniformly or colored in plural colors depending on the light distribution characteristics. Without forming the optical shape portion 7, wavelength converted light may be radiated outside directly from the opening 4A of the case 4.

The mounting substrate 8 may be formed of a ceramic material or organic material other than Al. The insulating material of the insulating layer 80 may include a ceramic material instead of polyimide. Further, it may be formed of a glass epoxy substrate or a ceramic substrate for general purpose.

### Second Embodiment

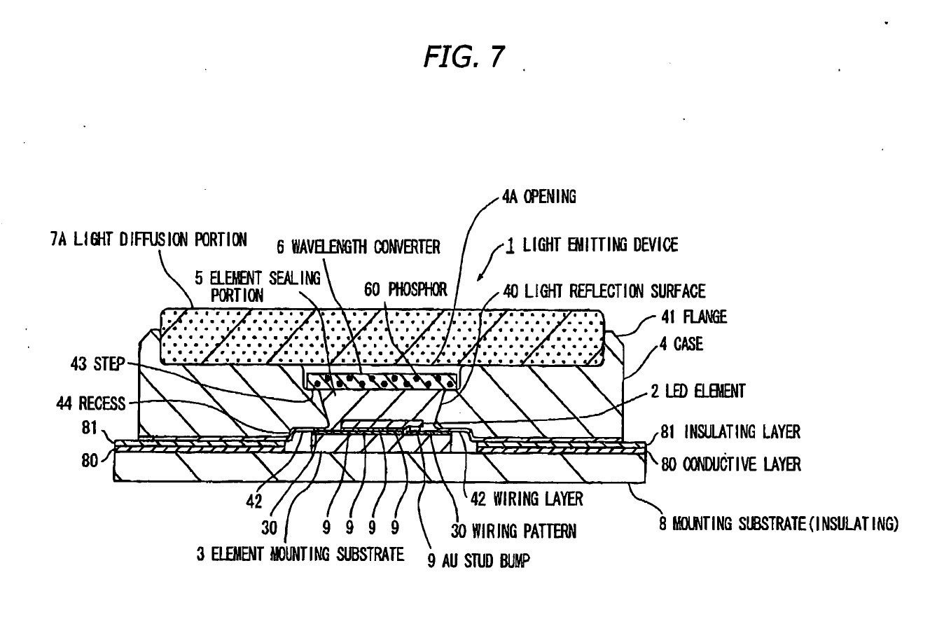

FIG. 7 is a cross sectional view showing a light emitting device in the second preferred embodiment according to the invention. In the following explanation, same components as in the first embodiment are indicated by using the same reference numerals.

Construction of light emitting device 1

In this light emitting device 1, a milky white light diffusion portion 7A is provided on the surface of the case 4, instead of the optical shape portion 7 in the first embodiment.

The entire light diffusion portion 7A emits a milky white light by diffusing incident light from the wavelength converter 6 inside thereof.

Effects of the second embodiment

The second embodiment, in addition to the effects of the first embodiment, has the effect that the light emitting device 1 can be provided which emits the milky white light according to the shape of the case 4. Furthermore, since the thickness of the optical member (light diffusion portion 7A) provided at the upper part of the case 4 can be reduced, the entire thickness of the light emitting device 1 can be reduced.

### Third Embodiment

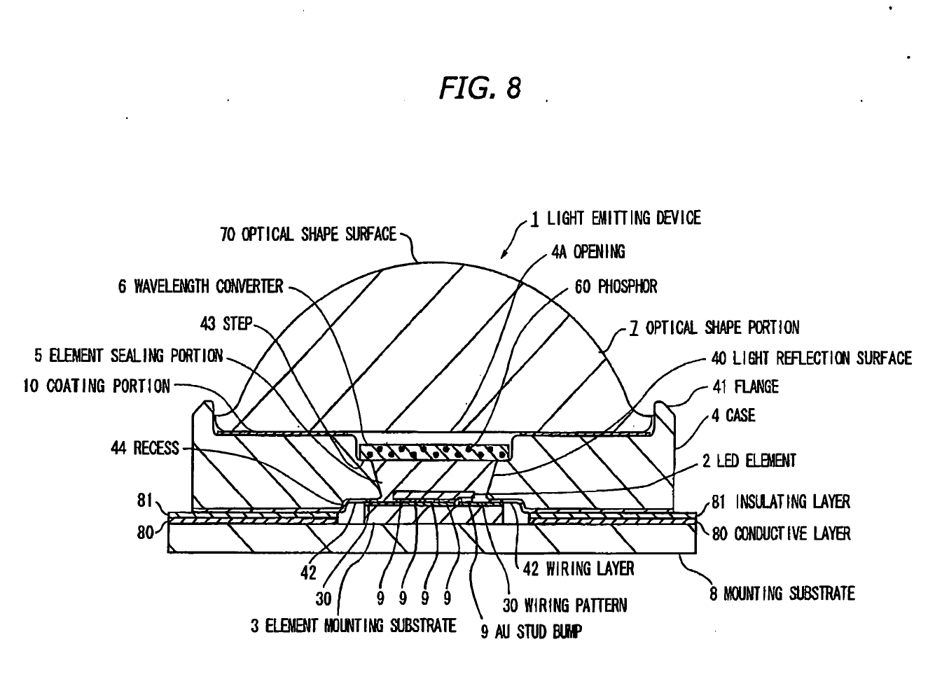

FIG. 8 is a cross sectional view showing a light emitting device in the third preferred embodiment according to the invention.

Construction of light emitting device 1

The light emitting device 1 is constructed such that a black coating portion 10 is provided on the surface of the case 4 in the first embodiment.

Effects of the third embodiment

The third embodiment, in addition to the effects of the first embodiment, has the effect that, by coating the surface of the case 4 in black, contrast between the turn-on and turn-off of the LED element 2 can be rendered very clear when it is viewed at the light radiation side so that the visual recognition can be enhanced. Hence, the visual misconception can be avoided in application on lamps such as a traffic light and an indicator. The coating color is not limited to black, but may include navy blue or the other color for improving the visual recognition. Instead of the coating, the coloring may be applied by gluing a seal or the like.

### Fourth Embodiment

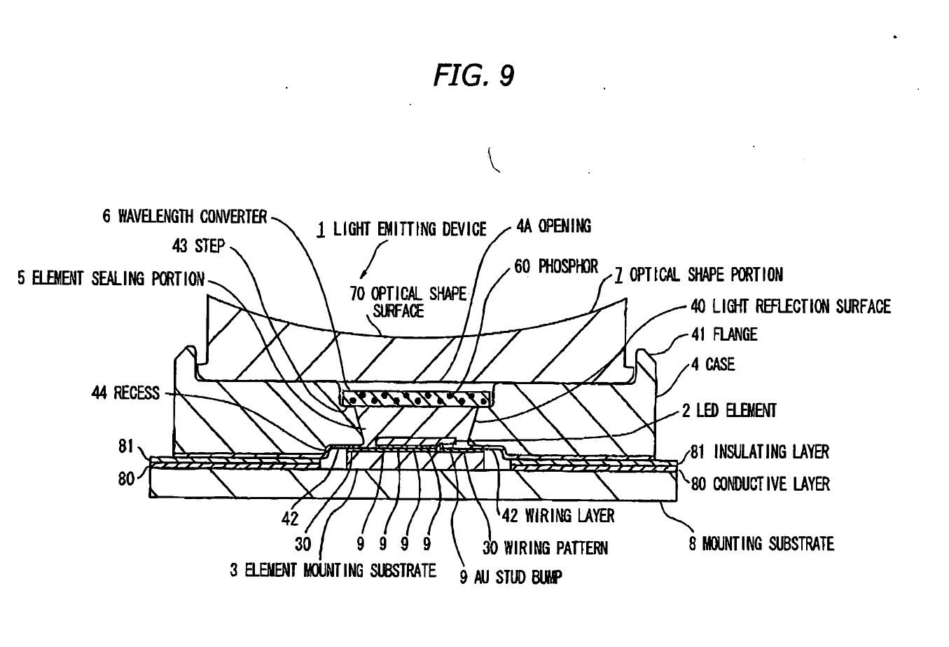

FIG. 9 is a cross sectional view showing a light emitting device in the fourth preferred embodiment according to the invention.

Construction of light emitting device 1

The light emitting device 1 is constructed such that the optical shape portion 7 with a concave optical shape surface 70 is provided instead of the hemispherical optical shape portion 7 as described in the first embodiment.

Effects of the fourth embodiment

The fourth embodiment, in addition to the effects of the first embodiment, has the effect that, by providing the optical shape portion 7 with the concave optical shape surface 70 on the case 4, incident light from the wavelength converter 6 can be radiated in diffusion.

### Fifth Embodiment

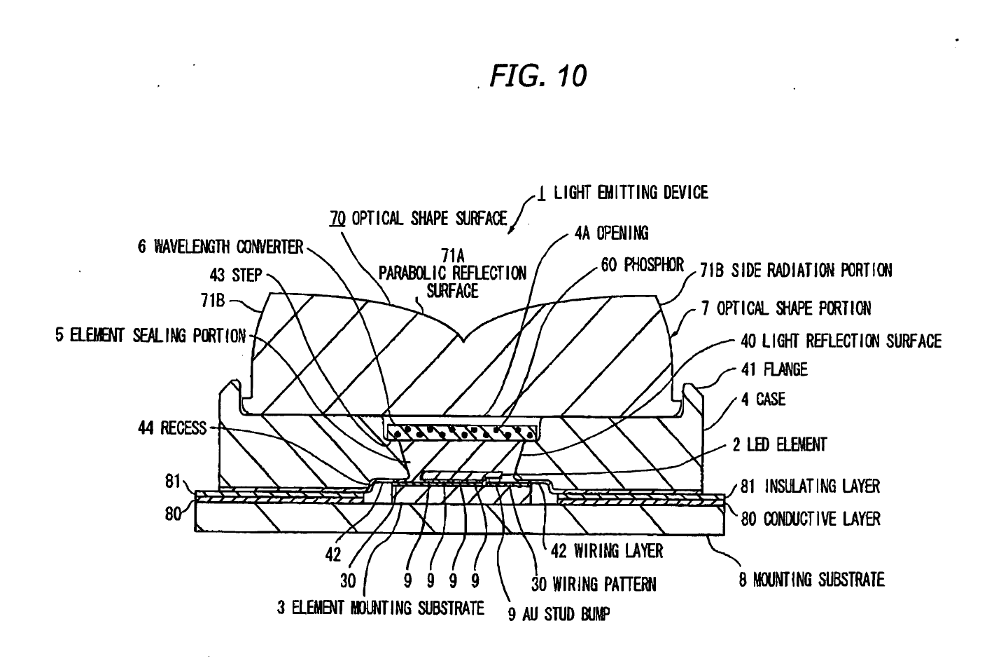

FIG. 10 is a cross sectional view showing a light emitting device in the fifth preferred embodiment according to the invention.

Construction of light emitting device 1

The light emitting device 1 is constructed such that the optical shape surface 70 of the optical shape portion 7 comprises a parabolic reflection surface 71A and a side radiation portion 71B, instead of the hemispherical optical shape portion 7 as described in the first embodiment.

The parabolic reflection surface 71A reflects light passing through the wavelength converter 6 nearly in horizontal direction to the optical axis. The reflected light is radiated outside from the side radiation portion 71B.

Effects of the fifth embodiment

The fifth embodiment, in addition to the effects of the first embodiment, has the effect that, by providing the optical shape portion 7 comprising the parabolic reflection surface 71A and the side radiation portion 71B on the case 4, wavelength-converted light can be radiated outside in the different direction than the optical axis direction of the LED element 2.

### Sixth Embodiment

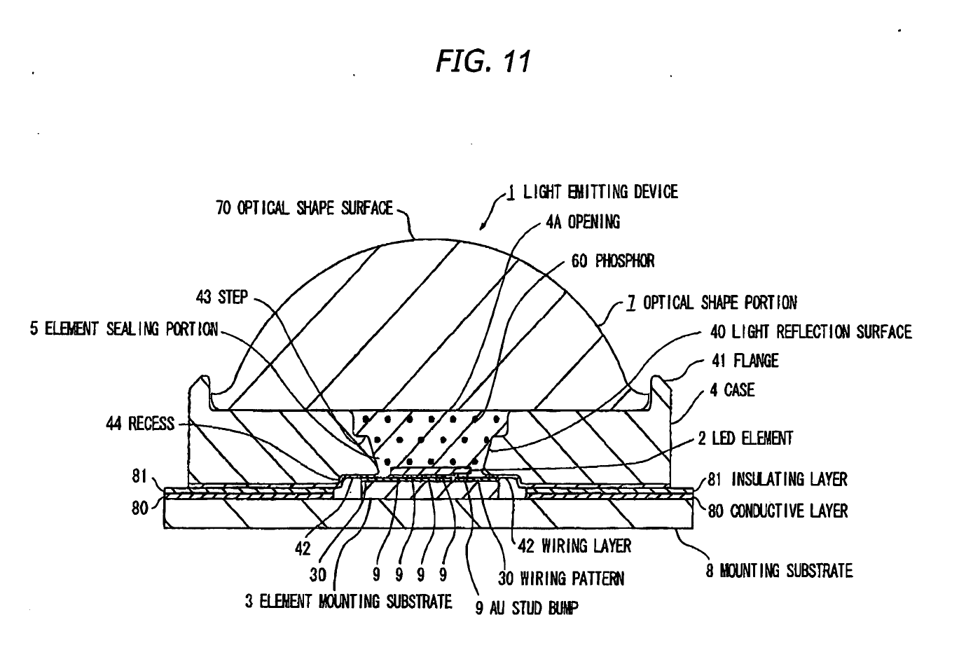

FIG. 11 is a cross sectional view showing a light emitting device in the sixth preferred embodiment according to the invention.

Construction of light emitting device 1

The light emitting device 1 is constructed such that the element sealing portion 5 for sealing the LED element 2 comprises YAG as the phosphor 60, instead of providing the wavelength converter 6 as described in the first embodiment.

Effects of the sixth embodiment

The sixth embodiment, in addition to the effects of the first embodiment, has the effect that the step of installing the wavelength converter 6 can be omitted to simplify the manufacturing process and to enhance the productivity.

### Seventh Embodiment

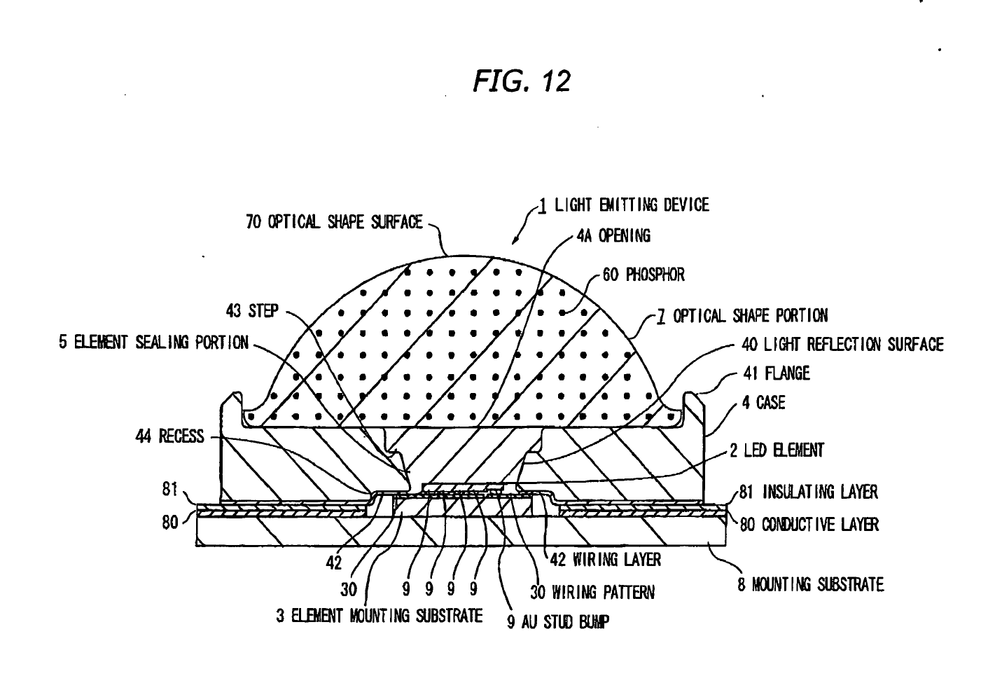

FIG. 12 is a cross sectional view showing a light emitting device in the seventh preferred embodiment according to the invention.

Configuration of light emitting device 1

The light emitting device 1 is constructed such that the optical shape section 7 is formed of a transparent resin containing the phosphor 60 instead of the wavelength converter 6 as described in the first embodiment.

Effects of the seventh embodiment

The seventh embodiment, in addition to the effects of the first and sixth embodiments, has the effect that the customer may freely select whether to use the wavelength converter 6 or not. For example, in order to provide the white light emitting device 1, the optical shape portion 7 containing the phosphor 60 can be installed, or in order to provide the blue light emitting device 1, the colorless and transparent optical shape portion 7 can be installed or not installed. Thus, the variation of the light emitting device 1 can be expanded without modifying the components disposed below the case 4.

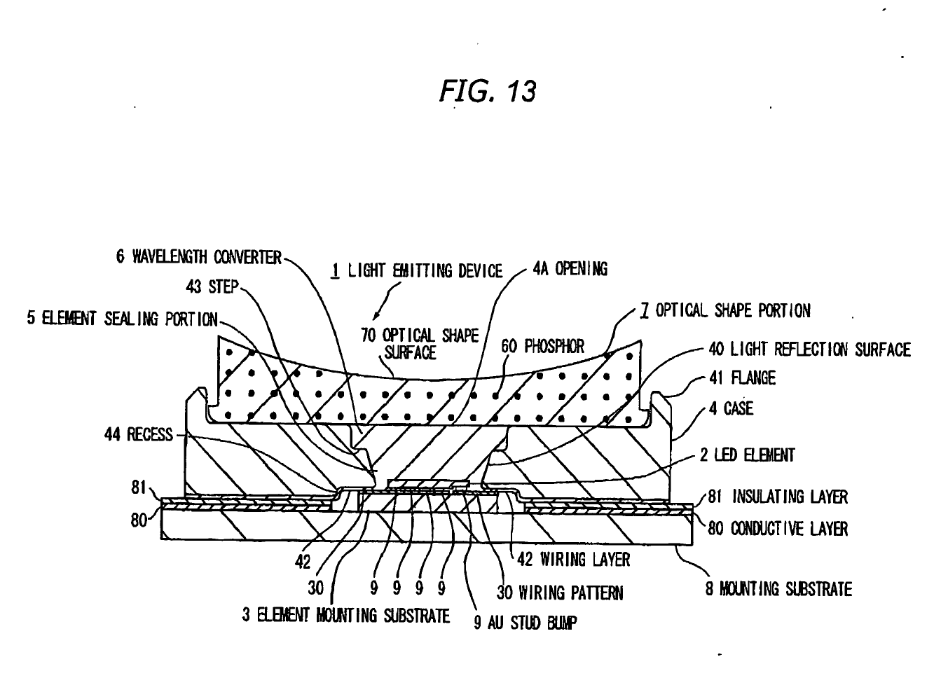

Alternatively, as shown in FIG. 13, the optical shape portion 7 containing the phosphor 60 may be formed into a concave shape.

### Eighth Embodiment

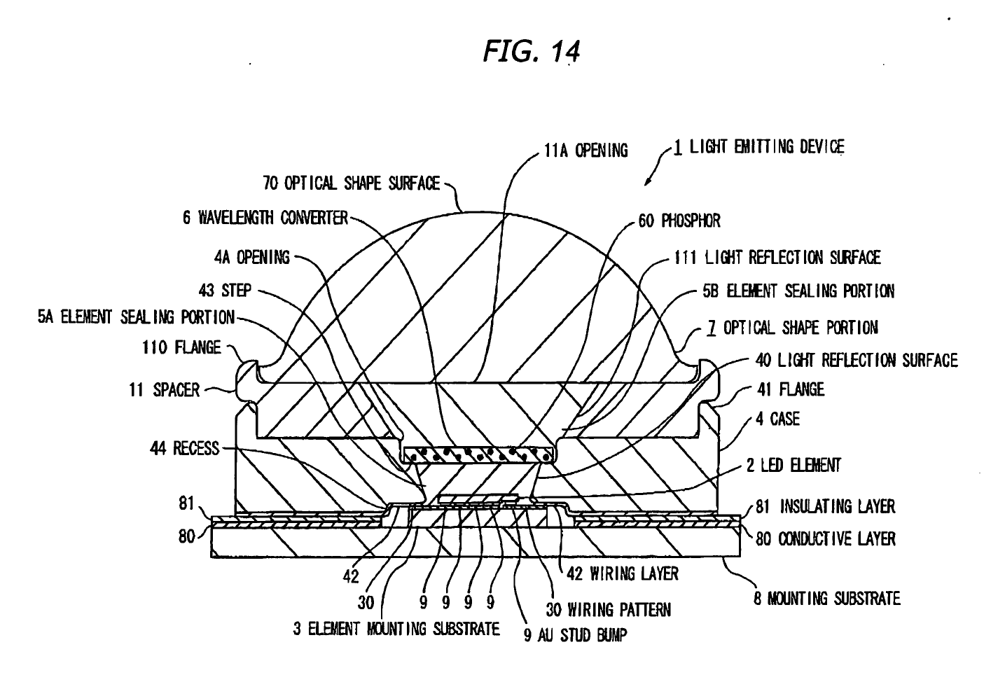

FIG. 14 is a cross sectional view showing a light emitting device in the eighth preferred embodiment according to the invention.

Configuration of light emitting device 1

The light emitting device 1 is constructed such that a spacer 11 is provided between the case 4 and the optical shape portion 7 as described in the first embodiment.

The spacer 11 is formed of the same Al₂O₃ as the case 4 and has an opening 11A provided at the center, formed penetrating from the surface through the bottom thereof. The inner wall of the opening 11A is provided with a light reflection surface 111 inclined such that the inside diameter is enlarged from the bottom to the light extraction direction. Thereby, light radiated from the LED element 2 is reflected to the light output direction. A flange 110 is formed on the periphery of the spacer 11, and the bottom of the spacer 11 has such a shape that can be engaged with the flange 41 of the case 4.

As shown in FIG. 14, the inside of the opening 4A of the case 4 is sealed by the element sealing portion 5A, and the inside of the opening 11A of the spacer 11 is sealed by an element sealing portion 5B. The light reflection surface 111 of the opening 11A is formed to be continuous with the light reflection surface 40 of the opening 4A. The element sealing portion 5B of the opening 11A may comprise a phosphor, or may be omitted.

Effects of the eighth embodiment

The eighth embodiment, in addition to the effects of the first embodiment, has the effect that, by disposing the spacer 11 on the case 4, the light reflection surface can be formed by combining the light reflection plane 40 and the light reflection plane 111. Thus, a desired light collecting shape can be formed easy by using the spacer 11 and an improved light radiation property and high emission efficiency can be obtained. Therefore, the radiation performance of white light can be easy changed without modifying the structure of the case 4.

### Ninth Embodiment

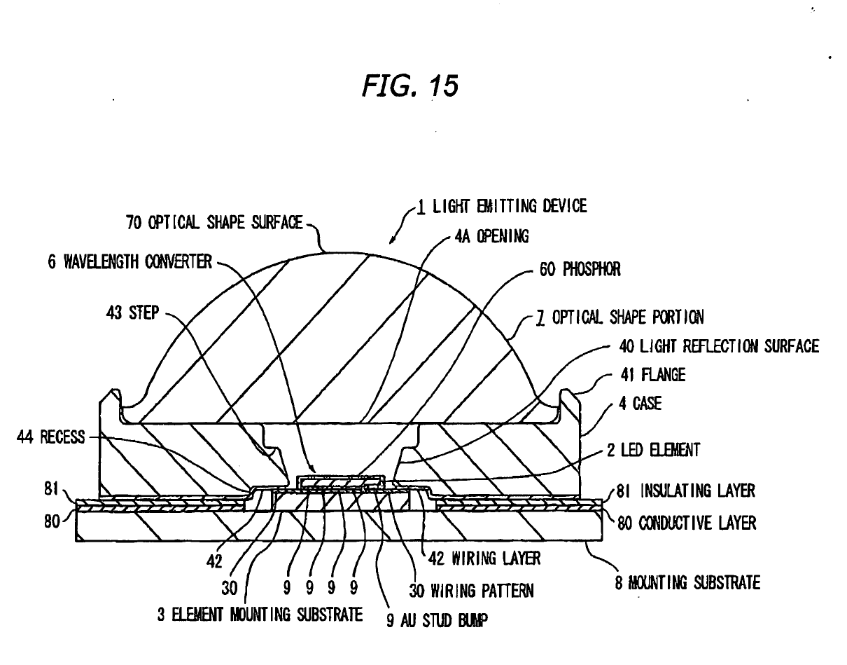

FIG. 15 is a cross sectional view showing a light emitting device in the ninth preferred embodiment according to the invention.

Construction of light emitting device 1

The light emitting device 1 is constructed such that, instead of the element sealing portion 5 containing the phosphor as explained in the sixth embodiment, the film wavelength converter 6 comprising a coating material containing the phosphor 60 is formed on the surface of the LED element 2.

The film wavelength converter 6 may comprise, for example, a transparent resin material such as silicone, or a transparent inorganic coating material containing YAG or the other phosphor. The film wavelength converter 6 can be formed by screen printing after the LED element 2 is mounted on the element mounting substrate 3. After forming the film wavelength converter 6, the case 4 is mounted and then the optical shape portion 7 is attached.

Effects of the ninth embodiment

In the ninth embodiment, since the LED element 2 is not sealed by the element sealing portion 5, thermal expansion of the element sealing portion 5 does not occur by heat generated at the LED element 2, so that the light emitting device 1 can be free of the peeling of the element sealing portion 5. Further, since the thin film wavelength converter 6 is provided on the element surface, the emission color of the light emitting device 1 can be uniformed without sacrificing the wavelength conversion characteristic while saving the amount of the phosphor 60.

### Tenth Embodiment

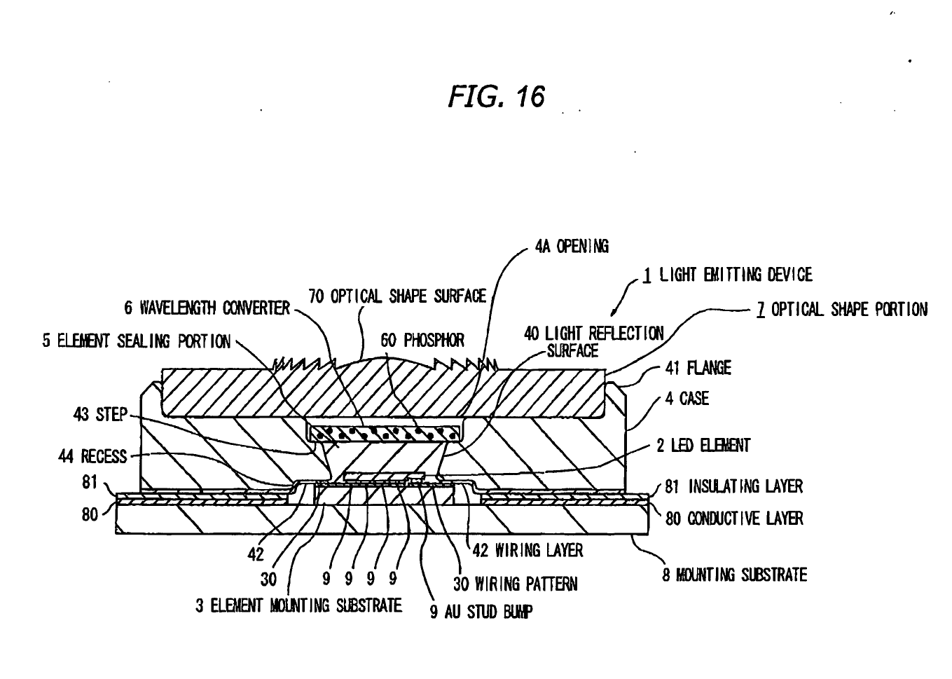

FIG. 16 is a cross sectional view showing a light emitting device in the tenth preferred embodiment according to the invention.

Construction of light emitting device 1

The light emitting device 1 is constructed such that the optical shape portion 7 has the optical shape surface 70 shaped like a Fresnel lens. Thereby, the optical shape portion 7 is reduced in thickness without sacrificing the light collecting performance.

Effects of the tenth embodiment

In the tenth embodiment, since the optical shape portion 7 is reduced in thickness while securing the light collecting performance, in addition to the effects of the first embodiment, the light emitting device 1 can be installed with a sufficient allowance even in an electronic device which is restricted in conditions such as its device size. The same effects can be obtained even when the blue light emitting device 1 is constructed without the wavelength converter 6.

### Eleventh Embodiment

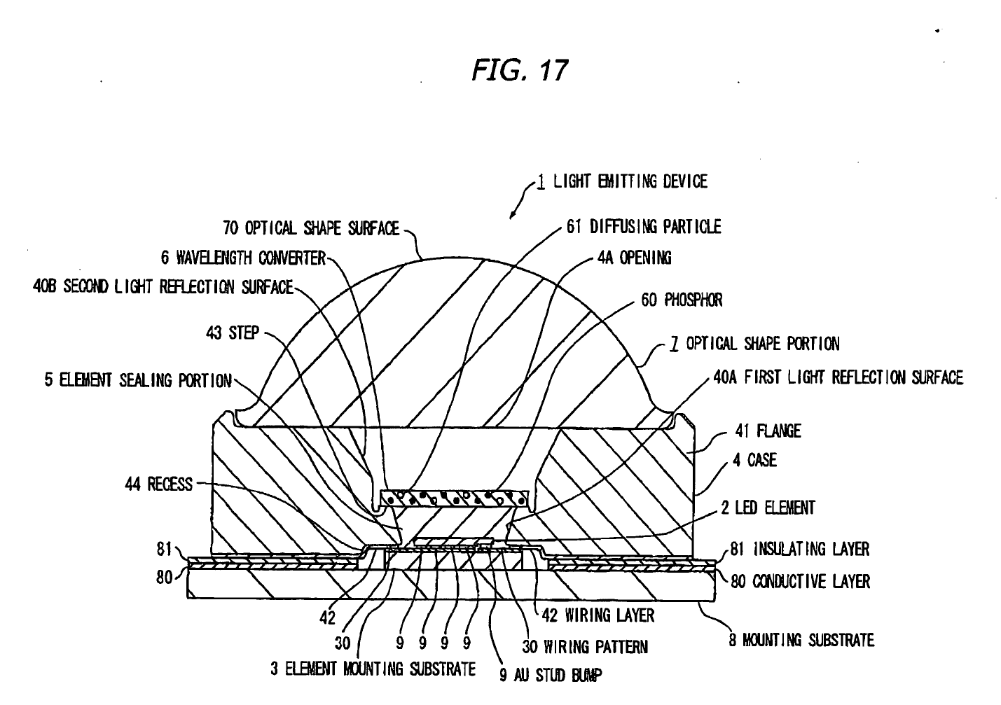

FIG. 17 is a cross sectional view showing a light emitting device in the eleventh preferred embodiment according to the invention.

Construction of light emitting device 1

The light emitting device 1 is constructed such that the case 4 comprises a first light reflection surface 40A formed on the bottom side of the inner wall of the opening 4A, and a second light reflection surface 40B formed on the light extraction side of the inner wall of the opening 4A. The first light reflection surface 40A is enlarged in its inside diameter from the bottom to the light extraction side to reflect light emitted from the LED element 2 toward the light extraction side. The second light reflection surface 40B is enlarged in its inside diameter from the bottom to the light extraction side to reflect light passing through the wavelength converter 6 toward the optical shape surface 70. Also in this embodiment, the element mounting substrate 3 may be solder-bonded to the mounting substrate 8 by solder reflow.

The inside of the first light reflection surface 40A is filled with the element sealing portion 5, and the inside of the second light reflection surface 40B is vacant. The upper surface of the element sealing portion 5 is made flush with the step 43, and the plate wavelength converter 6 is mounted on the element sealing portion 5 and the step 43.

Diffusing particles 61 are mixed in the wavelength converter 6. The diffusing particles 61 are formed of, e.g., a white material such as silica and titanium oxide which may be transparent or not transparent. The diffusing particles 61 do not serve to generate any wavelength-converted light.

Effects of the eleventh embodiment

The eleventh embodiment has the effect that the light collecting performance can be further enhanced by forming the second light reflection surface 40B in addition to the first light reflection surface 40A. Especially, in this embodiment, since both light before passing through the wavelength converter 6 and light after passing through the wavelength converter 6 are collected, lights before and after the wavelength conversion can be effectively mixed to enhance the uniformity of light extracted from the light emitting device 1.

Furthermore, since the light passing through the wavelength converter 6 is diffused by the diffusing particles 61, light not wavelength-converted can be also diffused by the diffusing particles 61 while the wavelength-converted light can be diffused by the phosphor 60. Thus, the uniformity of the radiated light can be enhanced.

### Twelfth Embodiment

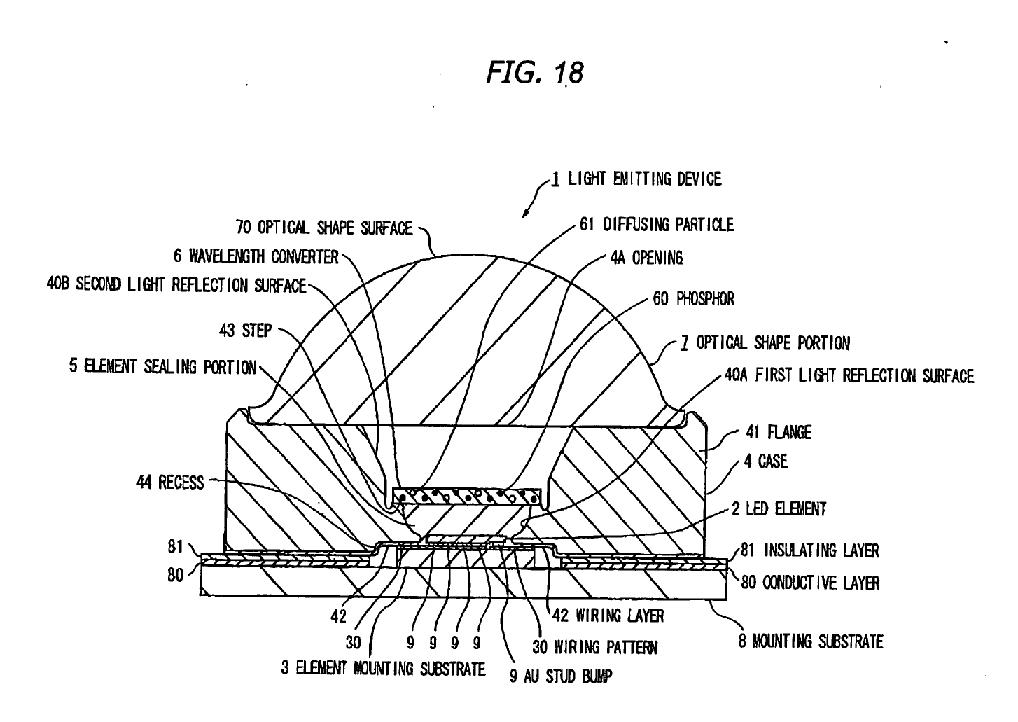

FIG. 18 is a cross sectional view showing a light emitting device in the twelfth preferred embodiment according to the invention.

Construction of light emitting device 1

The light emitting device 1 is constructed such that the first light reflection surface 40A as described in the eleventh embodiment is curved enlarged toward the light extraction side. As shown in FIG. 18, the first light reflection surface 40A is formed parabolic in its cross section. Thus, by the curved first light reflection surface 40A, the light reflection angle on the bottom side of the first light reflection surface 40A is different from that at the light extraction side.

Effects of the eleventh embodiment

The twelfth embodiment has the effect that, since the first light reflection surface 40A is curved, incident light to the first light reflection surface 40A from the LED element 2 can be effectively collected toward the light extraction direction to enhance the external light radiation efficiency.

### Thirteenth Embodiment

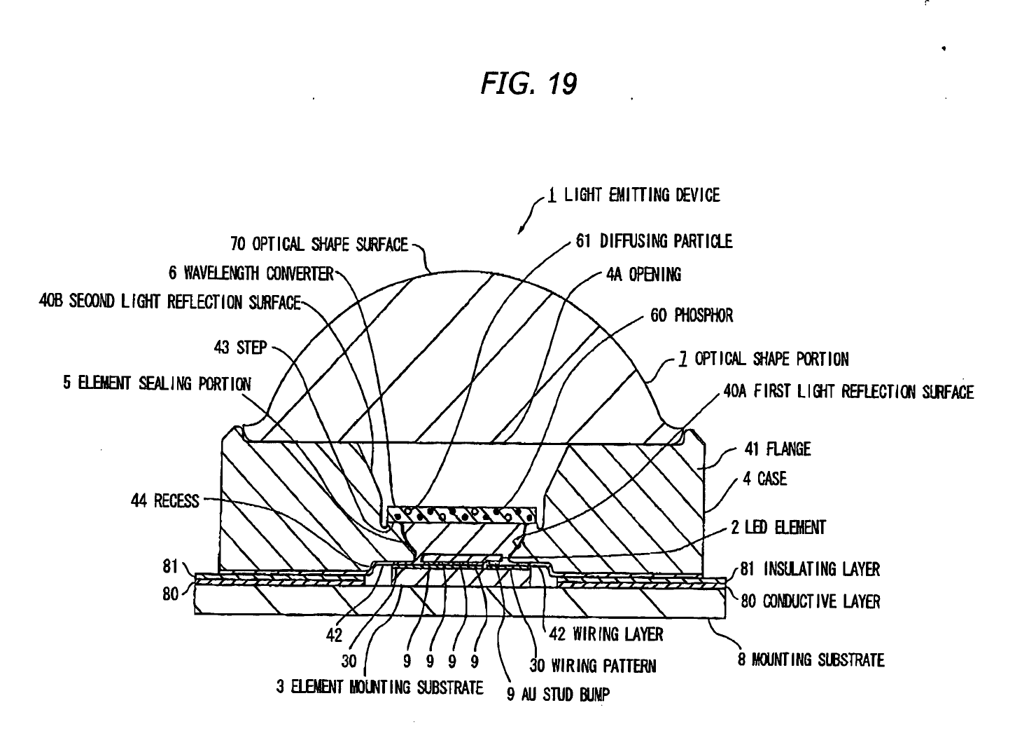

FIG. 19 is a cross sectional view showing a light emitting device in the thirteenth preferred embodiment according to the invention.

Construction of light emitting device 1

The light emitting device 1 is constructed such that the first light reflection surface 40A as described in the eleventh embodiment is provided with plural inclined angles in its cross section formed continuously from the bottom side toward the light extraction side. For example, the first light reflection surface 40A is provided with three inclined angles which are increased in angle to the bottom from the bottom side toward the light extraction side.

Effects of the thirteenth embodiment

The thirteenth embodiment has the effect that, since the first light reflection surface 40A is provided with the plural inclined angles such that the light reflection angle on the bottom side of the first light reflection surface 40A is different from that at the light extraction side, incident light to the first light reflection surface 40A from the LED element 2 can be effectively collected toward the light extraction direction to enhance the external light radiation efficiency.

### Fourteenth Embodiment

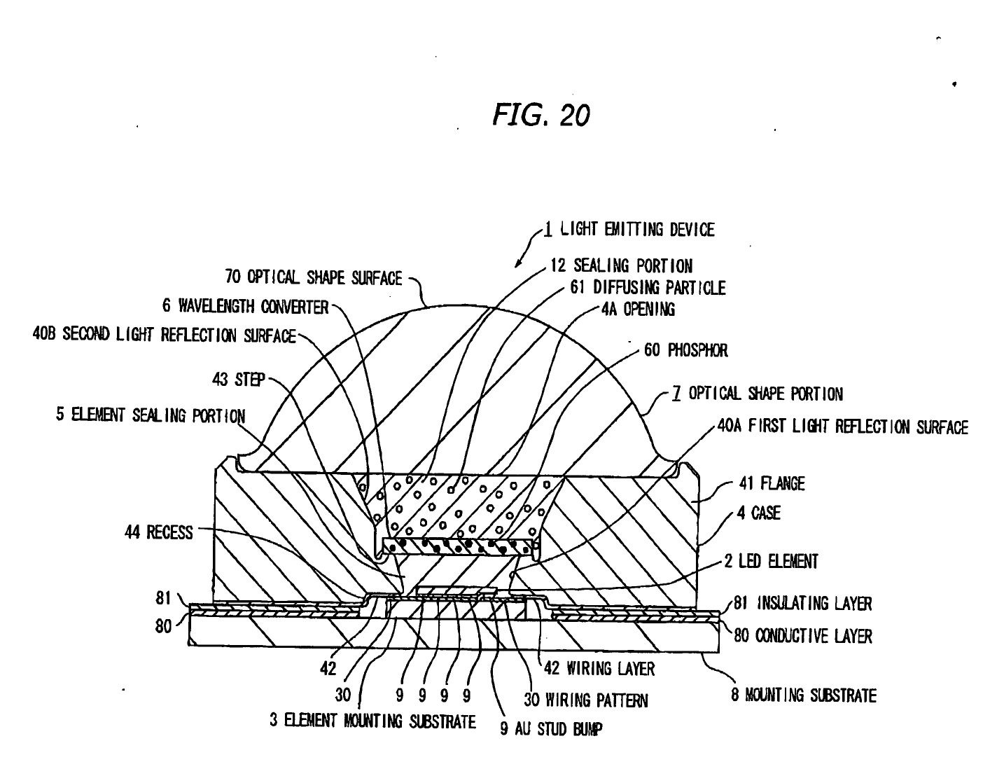

FIG. 20 is a cross sectional view showing a light emitting device in the fourteenth preferred embodiment according to the invention.

Construction of light emitting device 1

The light emitting device 1 is constructed such that the opening 4A above the wavelength converter 6 is sealed by filling therein silicone with heat resistance to form a sealing portion and to seal the wavelength converter 6. Namely, the inside of the first light reflection surface 40A is sealed by the element sealing portion 5, and the inside of the second light reflection surface 40B is sealed by the sealing portion 12. In this embodiment, the diffusing particles 61 are mixed in the sealing portion 12 rather than the wavelength converter 6. The diffusing particles 61 are formed of, e.g., a white material such as silica and titanium oxide which may be transparent or not transparent.

Effects of the fourteenth embodiment

The fourteenth embodiment has the effect that, since light passing through the wavelength converter 6 is subsequently diffused by the diffusing particles 61, the uniformity of incident light to the optical shape portion 7 can be enhanced.

Further, since the sealing portion 12 formed of silicone is filled between the optical shape portion 7 such that the region from the wavelength converter 6 to the optical shape portion 7 is formed of the resin materials, the refractive index does not change significantly therebetween. Therefore, the critical angle at the interface between adjacent materials of the wavelength converter 6, the sealing portion 12 and the optical shape portion 7 can be rendered large so that the light extraction efficiency can be enhanced.

### Fifteenth Embodiment

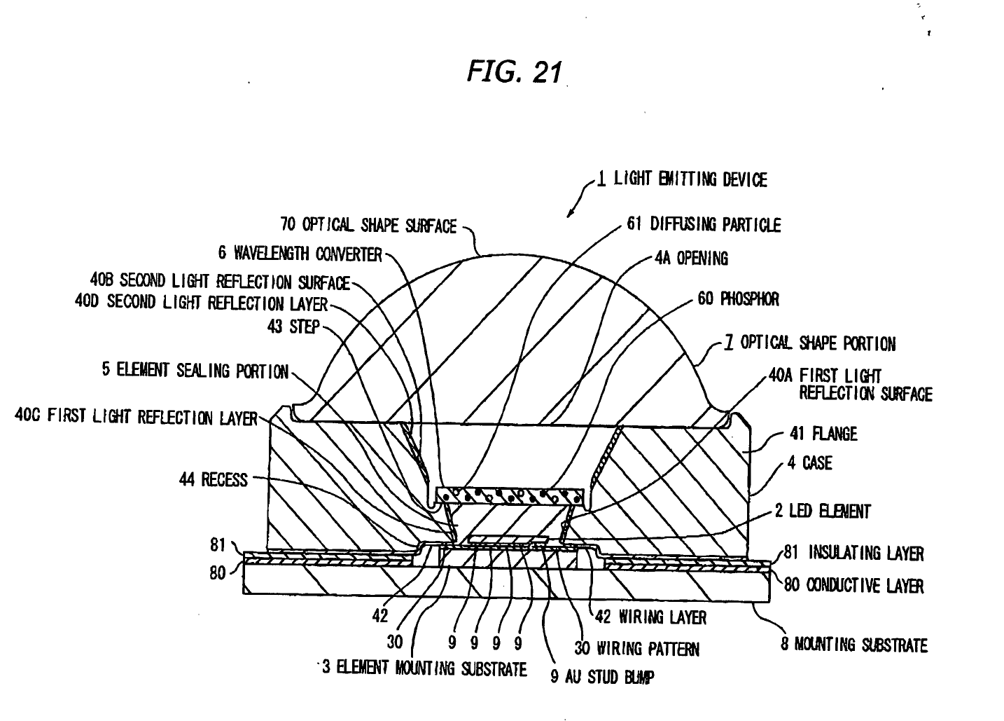

FIG. 21 is a cross sectional view showing a light emitting device in the fifteenth preferred embodiment according to the invention.

Construction of light emitting device 1

The light emitting device 1 is constructed such that a first light reflection layer 40C and a second light reflection layer 40D are formed on the first light reflection surface 40A and the second light reflection surface 40B, respectively. The first light reflection layer 40C and the second light reflection layer 40D are formed of, e.g., metal such as Al and Ag which has a higher reflectivity than the case 4 of Al₂O₃ and formed on the inner wall of the opening 4A by deposition etc.

Effects of the fifteenth embodiment

The fifteenth embodiment has the effect that the external radiation efficiency can be enhanced by covering the first light reflection surface 40A and the second light reflection surface 40B with the high-reflectivity first light reflection layer 40C and the second light reflection layer 40D, respectively.

Although the invention has been described with respect to the specific embodiments for complete and clear disclosure, the appended claims are not to be thus limited but are to be construed as embodying all modifications and alternative constructions that may occur to one skilled in the art which fairly fall within the basic teaching herein set forth.

What is claimed is:

1. A light emitting device, comprising:
an emitting element; and
an element mounting portion on which the emitting element is mounted,
wherein the element mounting portion comprises aluminum nitride.

2. A light emitting device, comprising:
an emitting element;
an element mounting portion on which the emitting element is mounted; and
a case comprising an opening to extract light emitted from the light emitting element, and a wiring portion for the element mounting portion and an external electrical connection, the wiring portion being provided on amounting surface on an opposite side to a light extraction side of the opening.

3. A light emitting device, comprising:
an emitting element;
an element mounting portion on which the emitting element is mounted;
a case comprising an opening to extract light emitted from the light emitting element, and a wiring portion for the element mounting portion and an external electrical connection, the wiring portion being provided on amounting surface on an opposite side to a light extraction side of the opening; and
an optical shape portion attached to the case such that light emitted from the light emitting element is radiated in a direction according to an optical shape of the optical shape portion.

4. A light emitting device, comprising:
an emitting element;
an element mounting portion on which the emitting element is mounted;
a case comprising an opening to extract light emitted from the light emitting element, and a wiring portion for the element mounting portion and an external electrical connection, the wiring portion being provided on amounting surface on an opposite side to a light extraction side of the opening;
a wavelength converter that is operable to convert a wavelength of light emitted from the light emitting element and to generate the wavelength-converted light; and
an optical shape portion attached to the case such that light emitted from the light emitting element is radiated in a direction according to an optical shape of the optical shape portion.

5. A light emitting device, comprising:
an emitting element;
an element mounting portion on which the emitting element is mounted;
a case comprising an opening to extract light emitted from the light emitting element, and a wiring portion for the element mounting portion and an external electrical connection, the wiring portion being provided on a mounting surface on an opposite side to a light extraction side of the opening; and
an optical shape portion that is operable to convert a wavelength of light emitted from the light emitting element and to radiate the wavelength-converted light in a direction according to an optical shape of the optical shape portion.

6. The light emitting device according to claim 2, wherein:
the case further comprises a first light reflection surface provided on a bottom side of an inner wall of the opening, and a second light reflection surface provided on the light extraction side of the inner wall of the opening, the second light reflection surface comprising a shape different from that of the first light reflection surface.

7. The light emitting device according to claim 6, wherein:
the first light reflection surface is curved.

8. The light emitting device according to claim 6, wherein:
at least one of the first light reflection surface and the second light reflection surface is covered with a metal comprising a higher reflectivity than the case.

9. The light emitting device according to claim 1, wherein:
the element mounting portion is disposed such that its bottom surface is made flush with a surface of an external mounting substrate and the bottom surface is surface-contacted to the surface of the external mounting substrate.

10. The light emitting device according to claim 1, wherein:
the element mounting portion is disposed such that its bottom surface is made flush with a surface of a conductive layer provided on an external mounting substrate.

11. The light emitting device according to claim 2, wherein:
the element mounting portion comprises: a first surface provided with a wiring pattern that is electrically connected to the light emitting element and is electrically connected to the wiring portion of the case; and a second surface provided on an opposite side to the first surface and disposed nearly flush with a surface of an external mounting substrate such that heat generated from the light emitting element is externally released through the external mounting substrate.

12. The light emitting device according to claim 2, wherein:
the element mounting portion is formed of a high heat conductive material.

13. The light emitting device according to claim 4, wherein:
the wavelength converter is disposed on a light extraction side of a sealing material to seal the light emitting element disposed in the opening of the case.

14. The light emitting device according to claim 4, wherein:
the wavelength converter comprises a phosphor-containing sealing material to seal the light emitting element disposed in the opening of the case.

15. The light emitting device according to claim 2, further comprising:
a spacer provided on a light extraction side of the case,
wherein the spacer comprises a second opening on an inner wall of which a second light reflection surface is provided, and
the second light reflection surface is formed continuously with a first light reflection surface provided on an inner wall of the opening of the case.

16. The light emitting device according to claim 2, wherein:
the element mounting portion comprises aluminum nitride.

17. The light emitting device according to claim 1, wherein:
the light emitting element is flip-mounted on the element mounting portion.

18. The light emitting device according to claim 1, wherein:
the light emitting element comprises a group III nitride-based compound semiconductor.

19. The light emitting device according to claim 4, wherein:
the wavelength converter comprises a YAG phosphor to be excited by a blue light emitted from the light emitting element to radiate a yellow light.

20. The light emitting device according to claim 4, wherein:
the wavelength converter comprises a RGB phosphor to be excited by an ultraviolet light emitted from the light emitting element to radiate a red light, a green light and a blue light.

21. The light emitting device according to claim 4, wherein:
the wavelength converter comprises a diffusing particle to diffuse light passing through the wavelength converter.

22. The light emitting device according to claim 4, wherein:
the case further comprises a first light reflection surface provided on a bottom side from the wavelength converter of an inner wall of the opening, and a second light reflection surface provided on the light extraction side from the wavelength converter of the inner wall of the opening.
